(19) United States
(12) Patent Application Publication
(10) Pub. No.: US 2014/0176204 A1
(43) Pub. Date: Jun. 26, 2014

(54) Phase locked loop system and working method thereof

(71) Applicant: Fangping Fan, Chengdu (CN)

(72) Inventor: Fangping Fan, Chengdu (CN)

(73) Assignee: IPGOAL MICROELECTRONICS (SICHUAN) CO., LTD., CHENGDU (CN)

(21) Appl. No.: 14/062,772

(22) Filed: Oct. 24, 2013

(30) Foreign Application Priority Data
Oct. 24, 2012 (CN) 201210410444.3

(51) Int. Cl. H03L 7/07

(52) U.S. Cl. CPC H03L 7/07
USPC 327/156

(57) ABSTRACT

A PLL system includes: an input end; an output end; a first PFD; a first CHP connected to the first PFD; a first LPF connected to the first CHP; a first VCO connected to the first CHP and the first LPF; a second PFD connected to the first VCO; a second CHP connected to the second PFD; a second LPF connected to the second CHP; a second VCO connected to the second CHP and the second LPF; a first DIV connected to the first PFD and the second VCO; and a second DIV connected to the second PFD and the second VCO. A working method of the PLL system is also provided, which can restrain input noise as well as phase noise of the second VOC in such a manner that noise of the PLL system is well restrained.

### BACKGROUND OF THE PRESENT INVENTION

1. Field of Invention

The present invention relates to a phase locked loop (PLL) system, and more particularly to a PLL system which can restrain noise of a PLL and a working method thereof.

2. Description of Related Arts

Referring to FIG. 1 of the drawings, a structural view of a PLL system according to a prior art is illustrated, wherein the PLL comprises:

a phase frequency detector (PFD);

a charge bump (CHP);

a low-pass filter (LPF);

a voltage-controlled oscillator (VCO); and

a digital frequency divider (DIV);

wherein the PFD detects a phase difference between an input clock Fin and a feedback clock Fb, and generates a CHP control signals Vup and Vdn for controlling the CHP; the CHP charges or discharges a voltage end Vc under control of the Vup and the Vdn; the LPF filters out high dither of the Vc; the VCO generates an output clock Fout under control of the Vc; usually, the Fout is linear with a voltage of the Vc; the DIV divides a frequency of the Fout for obtaining the Fb.

The problem of the conventional PLL system is that the noise of the Fin and the VCO cannot be restrained at the same time. For restraining the noise of the Fin, a loop bandwidth We should be lower than 1/10 of the Fin. For restraining the noise of the VCO, the We should be as large as possible. Obviously, the loop bandwidth is difficult to be determined for both the Fin and the VCO.

### SUMMARY OF THE PRESENT INVENTION

An object of the present invention is to provide a PLL system and a working method thereof for restraining input noise as well as VOC noise.

Accordingly, in order to accomplish the above object, the present invention provides a PLL system, comprising:

an input end;

a first PFD connected to the input end;

a first CHP connected to the first PFD;

a first LPF connected to the first CHP;

a first VCO connected to the first CHP and the first LPF;

a second PFD connected to the first VCO;

a second CHP connected to the second PFD;

a second LPF connected to the second CHP;

a second VCO connected to the second CHP and the second LPF;

an output end connected to the second VCO;

a first DIV connected to the first PFD, the second VCO and the output end; and

a second DIV connected to the second PFD, the second VCO and the output end;

wherein the second PFD, the second CHP, the second LPF, the second VCO and the second DIV form an inner loop; and the inner loop, the first PFD, the first CHP, the first LPF, the first VCO and the first DIV form an outer loop.

A working method of the PLL system is also provided, comprising steps of:
a) inputting an input clock Fin through the input end, and inputting the Fin as well as a feedback clock of the outer loop, which is a Fb1, into the first PFD, comparing a phase of the Fin with a phase of the Fb1 by the first PFD, then outputting first CHP control signals Vup1 and Vdn1;
b) charging or discharging the first LPF by the first CHP under control of the Vup1 and the Vdn1 for generating a first voltage Vc1; at the meantime, filtering the Vc1 by the first LPF for stabilizing the Vc1;
c) taking the Vc1 as a control voltage of the first VOC, and transforming the Vc1 into an inner loop input clock Fs by the first VOC;
d) inputting the Fs and a feedback clock of the inner loop, which is a Fb2, into the second PFD, comparing a phase of the Fs with a phase of the Fb2 by the second PFD, then outputting second CHP control signals Vup2 and a Vdn2;
e) charging or discharging the second LPF by the second CHP under control of the Vup2 and the Vdn2 for generating a second voltage Vc2; at the meantime, filtering the Vc2 by the second LPF for stabilizing the Vc2;
f) taking the Vc2 as a control voltage of the second VOC, and transforming the Vc2 into an output clock Fout by the second VOC;
g) dividing the Fout by the second DIV for obtaining the Fb2; continuously comparing the Fb2 with the Fs by the second PFD and gradually adjusting an inner loop until the phase of the Fb2 is completely the same as the phase of the Fs; and
h) dividing the Fout by the first DIV for obtaining the Fb1; continuously comparing the phase of the Fb1 with the phase of the Fout by the first PFD and gradually adjusting an outer loop until the phase of the Fb1 is completely the same as the phase of the Fin.

A working principle of the present invention is as follows. The inner loop is formed by the second PFD, the second CHP, the second LPF, the second VCO and the second DIV, wherein the second PFD compares the phase of the Fb2 with the phase of the Fs and generates the Vup2 and the Vdn2 for controlling the second CHP, wherein pulse widths of the Vup2 and the Vdn2 are proportional to a phase difference of the Fs and the Fb2. The second CHP charges or discharges the second LPF under the control of the Vup2 and the Vdn2 for generating the Vc2, then the Vc2 is increased or decreased, wherein if the Vup2 is at a high level and the Vdn2 is at a low level, the second CHP charges the second LPF for increasing the Vc2; if the Vup2 is at a low level and the Vdn2 is at a high level, the second CHP discharges the second LPF for decreasing the Vc2. The Vc2 is filtered by the second LPF for decreasing high dither. The second VCO generates the Fout under control of the Vc2. Usually, the Fout is linear with the Vc2. The second DIV divides a frequency of the Fout for obtaining the Fb2. A division ratio of the second DIV is set to N2. Because frequency of the Fs is usually high, an inner loop bandwidth can be set to high. An inner loop gain is:

$${H}_{2} ( s ) = \frac{{A}_{2} ( s + w 1 )}{{s}^{2} ( s + w 2 )}$$

wherein A2 is a low-frequency gain of the inner loop, w1 is a zero-point of the inner loop, and w2 is a pole-point of the inner loop. The w1 and w2 is high and the inner loop bandwidth Wc2 is proportional to the w1 and w2. Therefore, the Wc2 is high for providing fast response and restraining phase noise of the second VOC more effectively. Furthermore, the frequency of the Fs is high. Therefore, even the loop bandwidth of the Wc2 is lower than 1/10 of the Fs, the loop bandwidth is still high.

The outer loop is formed by the inner loop, the first PFD, the first CHP, the first LPF, the first VCO and the first DIV, wherein the first PFD compares the phase of the Fin with the phase of the Fb1 and generates the Vup1 and the Vdn1 for controlling the first CHP, wherein pulse widths of the Vup1 and the Vdn1 are proportional to a phase difference of the Fin and the Fb1. The first CHP charges or discharges the first LPF under the control of the Vup1 and the Vdn1 for generating the Vc1, then the Vc1 is increased or decreased, wherein if the Vup1 is at a high level and the Vdn1 is at a low level, the first CHP charges the first LPF for increasing the Vc1; if the Vup1 is at a low level and the Vdn1 is at a high level, the first CHP discharges the first LPF for decreasing the Vc1. The Vc1 is filtered by the first LPF for decreasing high dither. The first VCO generates the Fs under control of the Vc1. Usually, the Fs is linear with the Vc1. The first DIV divides a frequency of the Fout for obtaining the Fb1. A division ratio of the first DIV is set to N1. Because frequency of the Fs is usually low, an output loop bandwidth can be set to low. An output loop gain is:

$${H}_{1} ( s ) = \frac{{A}_{1} ( s + w 3 )}{{s}^{2} ( s + w 4 )} \cdot \frac{N 2 \cdot {H}_{2} ( s )}{1 + {H}_{2} ( s )} \approx \frac{{A}_{1} ( s + w 3 )}{{s}^{2} ( s + w 4 )} \cdot N 2 \qquad ( 1 )$$

wherein A1 is a low-frequency gain of the outer loop, w3 is a zero-point of the outer loop, and w4 is a pole-point of the outer loop. The N2 is the division ratio of the second DIV. The H₂(s) is the input loop gain. The w3 and w4 are set to be far lower than the w1 and w2 and the outer loop bandwidth Wc1 is proportional to the w3 and w4. That is to say, the Wc1 is far lower than the Wc2, and a bandwidth in the formula (1) is the Wc1. For filtering noise of the Fin, the loop bandwidth of the Wc1 is lower than 1/10 of the Fin. Because the Wc1 is far less than the Wc2, the Wc1 will not affect the Wc2.

Therefore, when compared to the conventional technology, the PLL system according to the present invention has the inner loop. By adjusting the bandwidth of the inner loop, the phase noise of the second VOC can be restrained. And by adjusting the bandwidth of the outer loop, the input noise can be restrained in such a manner that a medium relationship of the conventional technology disappears and the noise of the PLL system is well restrained.

These and other objectives, features, and advantages of the present invention will become apparent from the following detailed description, the accompanying drawings, and the appended claims.

### BRIEF DESCRIPTION OF THE DRAWINGS

FIG. 1 is a structural view of a phase-locked loop system according to a prior art.

FIG. 2 is a structural view of a phase-locked loop system according to a preferred embodiment of the present invention.

FIG. 3 is a flow chart according to the preferred embodiment of the present invention.

### DETAILED DESCRIPTION OF THE PREFERRED EMBODIMENT

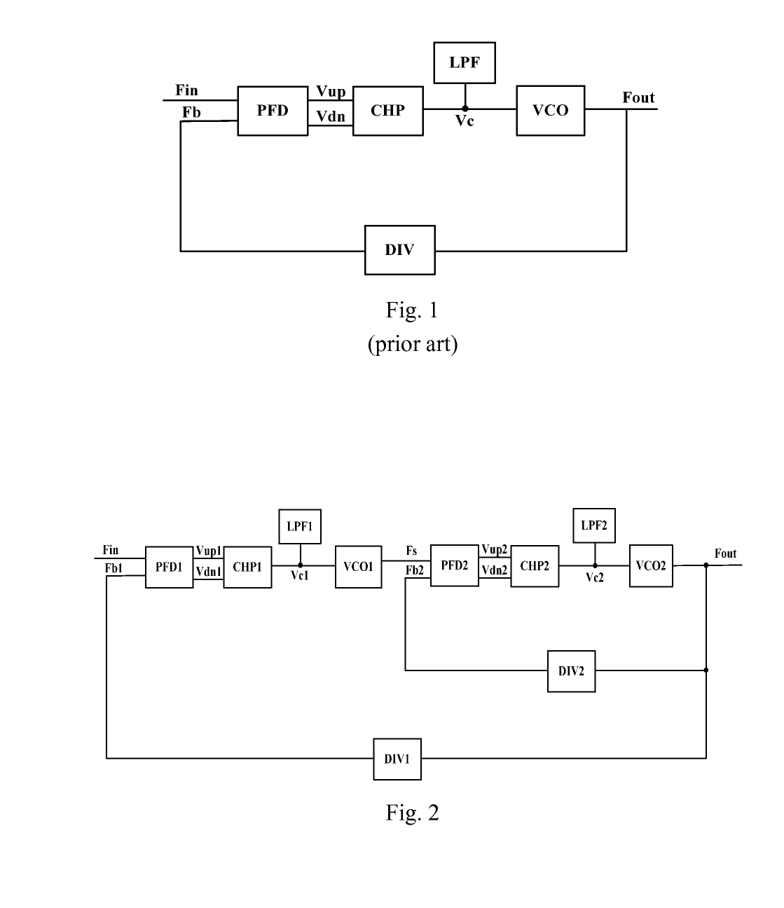

Referring to FIG. 2 of the drawings, a PLL system according to a preferred embodiment of the present invention is illustrated, comprising:

an input end;

a first PFD1 connected to the input end;

a first CHP1 connected to the first PFD1;

a first LPF1 connected to the first CHP1;

a first VCO1 connected to the first CHP1 and the first LPF1;

a second PFD2 connected to the first VCO1;

a second CHP2 connected to the second PFD2;

a second LPF2 connected to the second CHP2;

a second VCO2 connected to the second CHP2 and the second LPF2;

an output end connected to the second VCO2;

a first DIV1 connected to the first PFD1, the second VCO2 and the output end; and

a second DIV2 connected to the second PFD2, the second VCO2 and the output end;

wherein the second PFD2, the second CHP2, the second LPF2, the second VCO2 and the second DIV2 form an inner loop; and the inner loop, the first PFD1, the first CHP1, the first LPF1, the first VCO1 and the first DIV1 form an outer loop in such a manner that the PLL system has a nested structure; the outer loop has a low bandwidth for restraining the noise of a Fin; the inner loop has a high bandwidth for phase noise of the second VOC2, therefore, the PPL system according to the present invention respectively restrains the input noise and the phase noise of the second VOC2 by utilizing the two loops and has a great advantage on noise restraint.

A connection relationship of the present invention according to the preferred embodiment is as follows. The input end and a first end of the first DIV1 are connected to a first end of the first PFD1; a second end of the first PFD1 is connected to a first end of the first CHP1; a second end of the first CHP1 is respectively connected to the first LPF and a first end of the first VOC1; a second end of the first VOC1 and a first end of the second DIV2 are connected to a first end of the second PFD2; a second end of the second PFD2 is connected to a first end of the second CHP2; a second end of the second CHP2 is respectively connected to the second LPF2 and a first end of the second VOC2; a second end of the second VOC2 is respectively connected to a second end of the first DIV1, a second end of the DIV2 and the output end.

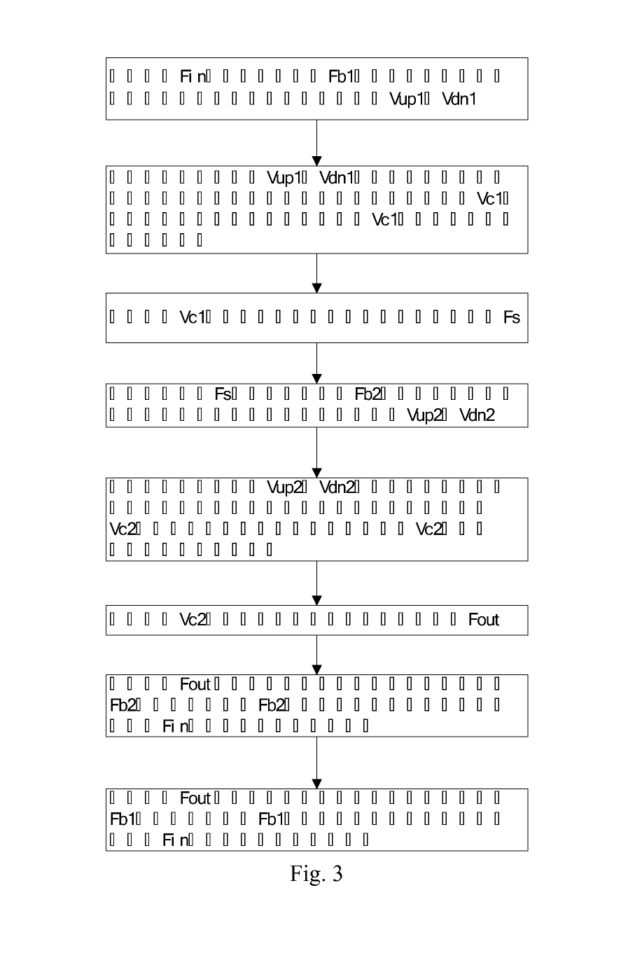

Referring to FIG. 3 of the drawings, a wording method of the PLL system according to the preferred embodiment of the present invention is illustrated, comprising:
a) inputting a Fin through the input end, and inputting the Fin as well as a Fb1 into the first PFD1, comparing a phase of the Fin with a phase of the Fb1 by the first PFD1, then outputting a Vup1 and a Vdn1;
b) charging or discharging the first LPF1 by the first CHP1 under control of the Vup1 and the Vdn1 for generating a Vc1; at the meantime, filtering the Vc1 by the first LPF1 for stabilizing the Vc1;
c) taking the Vc1 as a control voltage of the first VOC1, and transforming the Vc1 into a Fs by the first VOC1;
d) inputting the Fs and a Fb2 into the second PFD2, comparing a phase of the Fs with a phase of the Fb2 by the second PFD2, then outputting a Vup2 and a Vdn2;
e) charging or discharging the second LPF2 by the second CHP2 under control of the Vup2 and the Vdn2 for generating a Vc2; at the meantime, filtering the Vc2 by the second LPF2 for stabilizing the Vc2;
f) taking the Vc2 as a control voltage of the second VOC2, and transforming the Vc2 into a Fout by the second VOC2;
g) dividing the Fout by the second DIV2 for obtaining the Fb2; continuously comparing the Fb2 with the Fs by the second PFD2 and gradually adjusting an inner loop until the phase of the Fb2 is completely the same as the phase of the Fs; and
h) dividing the Fout by the first DIV1 for obtaining the Fb1; continuously comparing the phase of the Fb1 with the phase of the Fout by the first PFD1 and gradually adjusting an outer loop until the phase of the Fb1 is completely the same as the phase of the Fin.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A PLL system, comprising:
an input end;
a first PFD connected to said input end;
a first CHP connected to said first PFD;
a first LPF connected to said first CHP;
a first VCO connected to said first CHP and said first LPF;
a second PFD connected to said first VCO;
a second CHP connected to said second PFD;
a second LPF connected to said second CHP;
a second VCO connected to said second CHP and said second LPF;
an output end connected to said second VCO;
a first DIV connected to said first PFD, said second VCO and said output end; and
a second DIV connected to said second PFD, said second VCO and said output end.

2. The PLL system, as recited in claim 1, wherein said second PFD, said second CHP, said second LPF, said second VCO and said second DIV form an inner loop; and said inner loop, said first PFD, said first CHP, said first LPF, said first VCO and said first DIV form an outer loop.

3. The PLL system, as recited in claim 2, wherein said PLL system has a nested structure.

4. The PLL system, as recited in claim 1, wherein said input end and a first end of said first DIV are connected to a first end of said first PFD; a second end of said first PFD is connected to a first end of said first CHP; a second end of said first CHP is respectively connected to said first LPF and a first end of said first VOC; a second end of said first VOC and a first end of said second DIV are connected to a first end of said second PFD; a second end of said second PFD is connected to a first end of said second CHP; a second end of said second CHP is respectively connected to said second LPF and a first end of said second VOC; a second end of said second VOC is respectively connected to a second end of said first DIV, a second end of said DIV and said output end.

5. A working method of a PLL system, wherein said PLL system comprises:
an input end;
a first PFD connected to said input end;
a first CHP connected to said first PFD;
a first LPF connected to said first CHP;
a first VCO connected to said first CHP and said first LPF;
a second PFD connected to said first VCO;
a second CHP connected to said second PFD;
a second LPF connected to said second CHP;
a second VCO connected to said second CHP and said second LPF;
an output end connected to said second VCO;
a first DIV connected to said first PFD, said second VCO and said output end; and
a second DIV connected to said second PFD, said second VCO and said output end.

6. The method, as recited in claim 5, comprising steps of:
a) inputting a Fin through the input end, and inputting the Fin as well as a Fb1 into the first PFD, comparing a phase of the Fin with a phase of the Fb1 by the first PFD, then outputting a Vup1 and a Vdn1;
b) charging or discharging the first LPF by the first CHP under control of the Vup1 and the Vdn1 for generating a Vc1; at the meantime, filtering the Vc1 by the first LPF for stabilizing the Vc1;
c) taking the Vc1 as a control voltage of the first VOC, and transforming the Vc1 into a Fs by the first VOC;
d) inputting the Fs and a Fb2 into the second PFD, comparing a phase of the Fs with a phase of the Fb2 by the second PFD, then outputting a Vup2 and a Vdn2;
e) charging or discharging the second LPF by the second CHP under control of the Vup2 and the Vdn2 for generating a Vc2; at the meantime, filtering the Vc2 by the second LPF for stabilizing the Vc2;
f) taking the Vc2 as a control voltage of the second VOC, and transforming the Vc2 into a Fout by the second VOC;
g) dividing the Fout by the second DIV for obtaining the Fb2; continuously comparing the Fb2 with the Fs by the second PFD and gradually adjusting an inner loop until the phase of the Fb2 is completely the same as the phase of the Fs; and
h) dividing the Fout by the first DIV for obtaining the Fb1; continuously comparing the phase of the Fb1 with the phase of the Fout by the first PFD and gradually adjusting an outer loop until the phase of the Fb1 is completely the same as the phase of the Fin.

7. The method, as recited in claim 6, wherein the step b) specifically comprises: inputting the Vup1 and the Vdn1 into the first CHP, and charging or discharging the first LPF by the first CHP under the control of the Vup1 and the Vdn1 for generating the Vc1, then increasing or decreasing the Vc1, wherein if the Vup1 is at a high level and the Vdn1 is at a low level, the first CHP charges the first LPF for increasing the Vc1; if the Vup1 is at a low level and the Vdn1 is at a high level, the first CHP discharges the first LPF for decreasing the Vc1; at the meantime, filtering the Vc1 by the first LPF for decreasing high dither of the Vc1 and stabilizing the Vc1.

8. The method, as recited in claim 6, wherein the step e) specifically comprises: inputting the Vup2 and the Vdn2 into the second CHP, and charging or discharging the second LPF by the second CHP under the control of the Vup2 and the Vdn2 for generating the Vc2, then increasing or decreasing the Vc2, wherein if the Vup2 is at a high level and the Vdn2 is at a low level, the second CHP charges the second LPF for increasing the Vc2; if the Vup2 is at a low level and the Vdn2 is at a high level, the second CHP discharges the second LPF for decreasing the Vc2; at the meantime, filtering the Vc2 by the second LPF for decreasing high dither of the Vc2 and stabilizing the Vc2.
